(19) United States
(12) Patent Application Publication
(10) Pub. No.: US 2012/0012991 A1
(43) Pub. Date: Jan. 19, 2012

(54) Integrated shielding for a package-on-package system

(75) Inventors: Arvind Chandrasekaran, San Diego, CA (US); Jonghae Kim, San Diego, CA (US)

(73) Assignee: QUALCOMM INCORPORATED, San Diego, CA (US)

(21) Appl. No.: 12/855,376

(22) Filed: Aug. 12, 2010

Related U.S. Application Data
(60) Provisional application No. 61/364,860, filed on Jul. 16, 2010.

(51) Int. Cl. H01L 23/556; H01L 23/538; H01L 21/50

(52) U.S. Cl. 257/660; 438/107; 257/E21.499; 257/E23.115; 257/E23.169

(57) ABSTRACT

An electronic package-on-package system with integrated shielding. The package-on-package system includes a first package having a first die and a second package having a second die and a substrate. The system also includes a conductive shield having a first portion and a second portion. The first portion is disposed between the first die and the second die and the second portion is disposed between the substrate and the first portion. The first portion is coupled to the second portion for shielding the first die from the second die.

### CROSS-REFERENCE TO RELATED APPLICATIONS

This application claims the benefit of U.S. Provisional Patent Application Ser. No. 61/364,860, filed Jul. 16, 2010, which is hereby incorporated by reference.

### FIELD OF DISCLOSURE

This disclosure relates generally to electronic packaging, and in particular to reducing electromagnetic interference of a package-on-package system.

### BACKGROUND

In electronic packaging, there can be a high degree of sensitivity in integrated circuits due to electromagnetic interference (EMI) and radio-frequency interference (RFI) from external sources. This can be particularly true in package-on-package systems in which a first package is stacked on top of a second package. In these systems, the packages are being manufactured smaller and lighter, but are required to perform greater functionality. It can be difficult to reduce the effects of EMI and RFI, perform all of the required functionality, and still meet the reduced size requirements.

To overcome some of these disadvantages, a conventional package-on-package arrangement can include a separate shield casing that is attached to a die or package. The separate shield casing, however, can consume a great amount of area on a substrate and increases the overall height of the system. In another conventional system, an integrated metal coating can reduce some of the disadvantages described above, but it has limited benefit in a package-on-package system. For example, the EMI generated from electrical circuits in one of the packages can still negatively impact the other package(s).

Therefore, it would be desirable to develop an electronic package-on-package system with integrated shielding which could overcome the electromagnetic interference problems encountered in conventional electronic packages.

### SUMMARY

For a more complete understanding of the present disclosure, reference is now made to the following detailed description and the accompanying drawings. In an exemplary embodiment, an electronic package-on-package system is provided with integrated shielding. The package-on-package system includes a first package having a first die and a second package having a second die and a substrate. The system also includes a conductive shield having a first portion and a second portion. The first portion is disposed between the first die and the second die and the second portion is disposed between the substrate and the first portion. The first portion is coupled to the second portion for shielding the first die from the second die. The first portion can include a conductive plane, and in this embodiment, the conductive plane can be formed in the first package.

In form of the embodiment, a mold material is disposed between the substrate and conductive plane. In addition, one or more input/output connections are provided for coupling the first package to the substrate. The conductive shield can be continuous or discontinuous. In addition, the system can include a plurality of trenches formed in the mold material. The second portion of the conductive shield is formed in the plurality of trenches. Further, the conductive material can be formed of solder. Also, the second package can include a plurality of die. The plurality of die can be disposed between the conductive shield and the substrate. In addition, a third package can include a third die.

In another embodiment, an electronic system can include a first package having a first die and a second package having a second die and a substrate. The system can further include a conductive plane disposed between the first die and second die and a mold material disposed between the substrate and conductive plane. In addition, a conductive shield can be formed in the mold material such that the conductive shield is coupled to the conductive plane for shielding the first die from the second die.

The system can include one or more input/output connections for coupling the first package to the substrate. Also, the conductive shield can be continuous or discontinuous. The conductive shield can further be formed in trenches of the mold material. The conductive shield and conductive plane can be made of solder.

In one form of this embodiment, the conductive plane is formed in the first package. Also, the second package can include a plurality of die that is disposed between the conductive plane, conductive shield, and substrate. In addition, the system can include a third package having a third die.

In a different embodiment, a method of forming a package-on-package system with integrated shielding is provided. The method includes providing a first package and a second package such that the first package has a first die and the second package has a second die and a substrate. A mold material is applied between the substrate and a conductive plane and a plurality of trenches are formed in the mold material. The method also includes depositing a conductive material in the plurality of trenches to form a conductive shield and coupling the conductive shield to the conductive plane for shielding the first die from the second die.

In one form of this embodiment, the conductive shield can be continuous or discontinuous. In another form thereof, the conductive plane can be formed in the first package. The second package can include a plurality of die that is disposed between the conductive plane, conductive shield, and the substrate.

In another exemplary embodiment, an electronic package-on-package system includes a first package having a first die and a second package having a second die and a substrate. The system also includes a first means for shielding disposed between the first die and the second die and a mold material disposed between the substrate and conductive plane. In addition, the system includes a second means for shielding formed in the mold material such that the first means for shielding is coupled to the second means for shielding for shielding the first die from the second die.

The system can include one or more input/output connections for coupling the first package to the substrate. In addition, the second means for shielding can be continuous or discontinuous. The second means for shielding can be formed in trenches of the mold material. Also, the first means for shielding can be formed in the first package.

In one form of the embodiment, the second package can include a plurality of die such that the plurality of die is disposed between the first means for shielding, the second means for shielding, and the substrate. In another form thereof, a third package can include a third die.

The above-described embodiments are advantageous for shielding electromagnetic fields from package-on-package systems. These embodiments are effective for shielding single or multi-die applications. In addition, less area is required in the package for these assemblies, and unlike conventional packages, these embodiments do not increase the overall height of the package. Instead, the shielding can advantageously be integrated with the package to substantially shield a first die from a second die and vice versa.

### BRIEF DESCRIPTION OF THE DRAWINGS

FIG. 1 is a cross-sectional view of a first embodiment of a package-on-package system with integrated shielding;

FIG. 2 is a cross-sectional view of a second embodiment of a package-on-package system with integrated shielding;

FIG. 3 is a cross-sectional view of a different embodiment of a multiple package-on-package system with integrated shielding;

FIG. 4 is a partial cross-sectional top view of a package-on-package system with continuous integrated shielding;

FIG. 5 is a partial cross-sectional top view of a package-on-package system with discontinuous integrated shielding; and

FIG. 6 is a block diagram showing an exemplary wireless communication system in which it may be advantageous to use a package-on-package system with integrated shielding.

### DETAILED DESCRIPTION

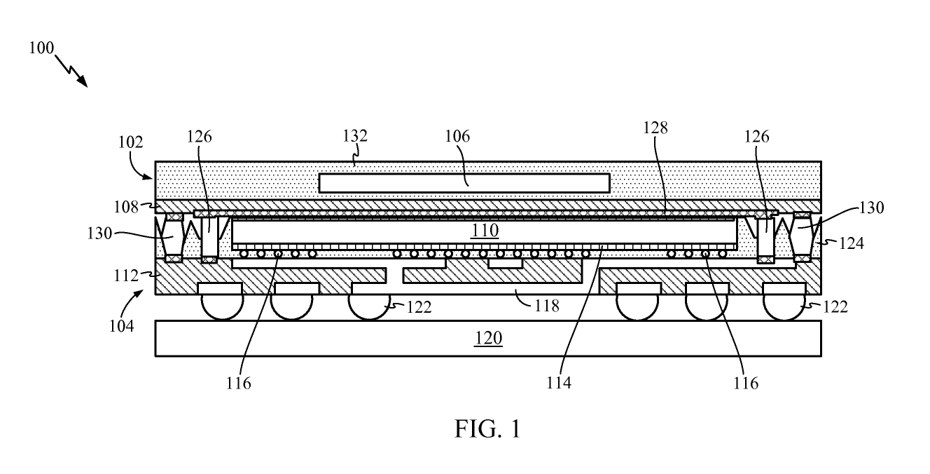

Referring to FIG. 1, an exemplary embodiment is provided of a package-on-package system 100 with integrated shielding. The system 100 includes a first package 102 and a second package 104. Although only two packages are shown, the system 100 can include a plurality of packages. The first package 102 includes a first die 106 coupled to a first substrate 108. Although not shown, the first die 106 can be conductively coupled by microbumps, solder balls, and/or an underfill layer to the first substrate 108. The first substrate 108 can be formed of silicon, glass, or any other substrate material. Likewise, the first die 106 can be made of silicon or other die material. The first die 106 can have through-vias or other conductive passages for coupling electrical components in the first package 102. Also, the first die 106 can be partially or completely surrounded by a mold compound 132 (e.g., epoxy-based material) for increasing the reliability of the first package 102.

Similar to the first package 102, the second package 104 can include a second die 110. The second die 110 is coupled to a second substrate 112. The second die 110 and second substrate 112 can be formed of silicon, glass, or other die and substrate material, respectively. The second die 110 can be coupled to the second substrate 112 by a plurality of microbumps 116. In addition, an underfill layer 114 is disposed between the second die 110 and the second substrate 112 to increase the reliability of the second package 104. In this embodiment, the second substrate 112 can include a plurality of conductive traces 118 for coupling the second die 110 to a chip, another package, or other electrical component. The second substrate 112 can also be coupled to another substrate or printed circuit board 120 by a plurality of solder bumps 122, for example.

The arrangement of the first package 102 stacked above the second package 104 can be referred to as a package-on-package assembly or system. In this embodiment, the first package 102 and second package 104 can be coupled to other electrical devices by a plurality of input/output (I/O) connections 130. In FIG. 1, the I/O connections 130 are formed on the outside of the second die 110, but in other embodiments, the I/O connections 130 can be formed in other desirable locations. Also, a mold compound 124 can be disposed between the first substrate 108 and second substrate 112 for increasing the reliability of the system 100. The mold compound 124, for example, can be any epoxy-based material that reduces warpage and other mechanical defects in the assembly process of electronic packaging.

As described above, there can be electromagnetic interference that can negatively affect the first die 106 and the second die 110 due to the close proximity of the dies to one another. Conventional packaging designs have attempted to resolve this problem by using a separate shield casing that attaches to the lower die in a package-on-package assembly. However, this can greatly increase the package footprint and height of the package thereby causing additional problems when incorporating the conventional package in an electrical device.

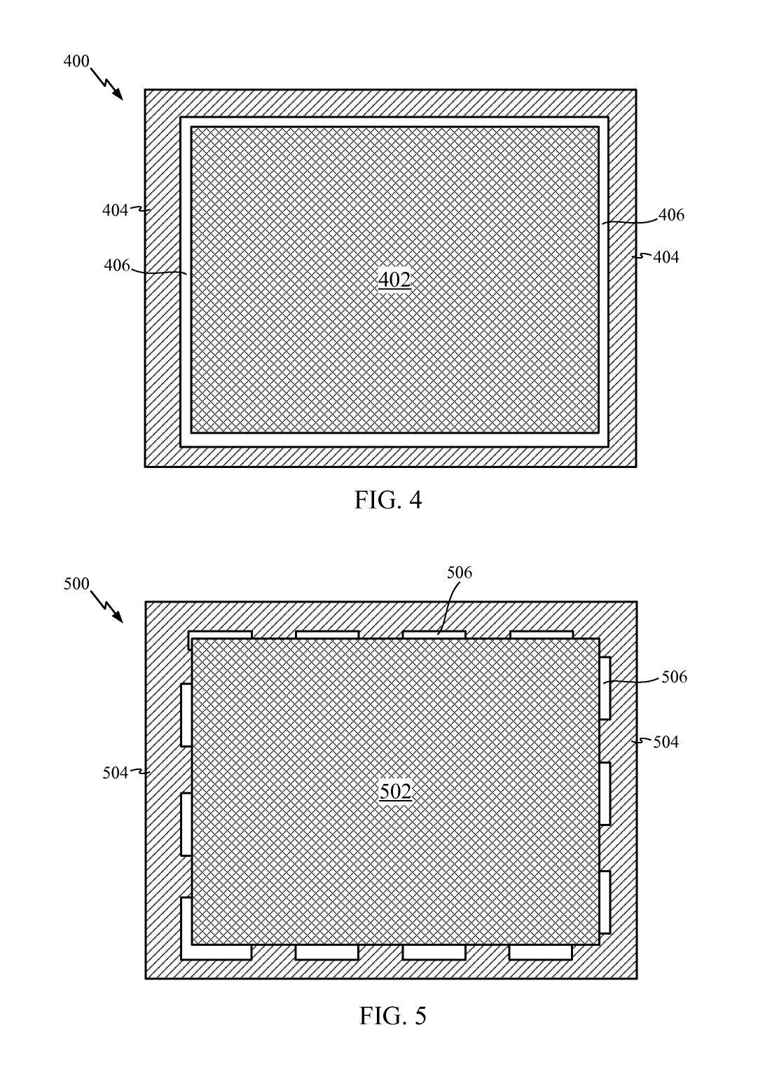

The embodiment of FIG. 1, however, overcomes the disadvantages of the prior art by integrally forming a conductive shield that prevents or reduces the electromagnetic interference between the first die 106 and second die 110. In this embodiment, a trench 126 is formed in the mold compound 124. There are several ways to form the trench 126 including laser drilling and etching. It is also possible to form a plurality of trenches 126 in the mold compound. The trench 126 is formed such that it substantially surrounds the second die 110. The embodiments shown in FIGS. 4 and 5 further illustrate the formation of the trench.

In FIG. 4, for example, a package-on-package assembly 400 is provided with a first package having a first die 402 and a second package having a second die 404. The first die 402 is disposed above the second die 404. In this assembly 400, a single, continuous trench 406 is formed around the second or bottom die 404. As the conductive material fills the trench 406, a single, continuous conductive shield is formed that surrounds the second or bottom die 404.

In FIG. 5, however, a different embodiment of a package-on-package assembly 500 is shown. In this embodiment, the assembly 500 also includes a first package having a first die 502 and a second package having a second die 504. However, in this assembly 500, a plurality of trenches 506 are formed around the second die 504 (e.g., the second die 504 is disposed beneath the first die 502). As conductive material is filled in each trench 506, a discontinuous conductive shield is formed that partially surrounds the second die 504. The distance between adjacent trenches 506 can be minimized such that the discontinuous conductive shield substantially (but not completely) surrounds the second die 504.

Referring back to FIG. 1, once the trench 126 is formed in the mold compound 124, conductive material such as copper can fill the trench 126. The conductive material therefore forms a conductive shield that surrounds the perimeter of the second die 110. To provide additional shielding, the conductive material in the trench 126 can be coupled to a conductive plane 128. The conductive plane 128 can be formed of copper or any other conductive material. In addition, the conductive plane 128 can be a metal ground layer or any other layer in the first substrate 108. Alternatively, the conductive plane 128 can be separate from the first substrate 108.

In another embodiment, the conductive plane 128 is not planar. Instead, the conductive plane 128 can have a non-planar configuration as desired. Regardless of the configuration of the conductive plane 128, an integrated conductive shield is formed by coupling the conductive plane 128 to the conductive material-filled trench 126. The integrated conductive shield separates the first die 106 from the second die 110 and therefore substantially reduces or eliminates electromagnetic interference between the dies. In addition, because the integrated conductive shield is integral to the package-on-package system 100, the system does not require additional footprint or increased height.

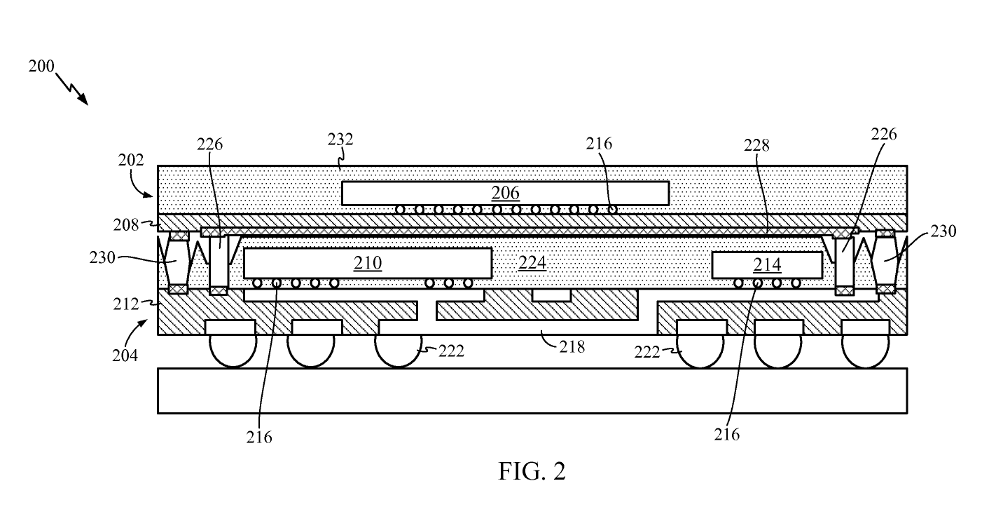

In a different embodiment, a package-on-package system 200 is shown in FIG. 2. The system 200 includes a first package 202 and a second package 204. The first package 202 is stacked or disposed above the second package 204. Similar to the embodiment of FIG. 1, the first package 202 can include a first die 206 and a first substrate 208. The first die 206 is coupled to the first substrate 208 by a plurality of solder bumps or microbumps 216. Although not shown, an underfill layer can be disposed between the first die 206 and the first substrate 208. Also, the first die 206 can be partially or completely surrounded by a mold compound 232. The mold compound 232 can be an epoxy-based material that reduces warpage, cracking, and other mechanical defects in the assembly process.

The second package 204 can include a second die 210 and a second substrate 212. In addition, the second package 204 also can include a third die 214 coupled to the second substrate 212. The second die 210 and third die 214 can be coupled to the second substrate by solder bumps or microbumps 216 and an underfill layer (not shown). In other embodiments, there can be additional die in the first package 202 and/or second package 204.

The second substrate 212 can have a plurality of conductive traces 218 formed therein. The plurality of conductive traces 218 can couple the second die 210 and third die 214 to another substrate or printed circuit board 220 by a plurality of solder bumps 222.

A mold compound 224 can be disposed between the first substrate 208 and second substrate 212. The mold compound 224 can be any epoxy-based material that can, for example, reduce warpage, cracking, or other mechanical defects during assembly. Similar to the system 100 shown in FIG. 1, the system 200 can include I/O connections 230 formed in the mold compound 224 for providing conductive connections to electrical devices. The first package 202 and second package 204 can be coupled to other electrical devices by utilizing the I/O connections 230.

The system 200 can further include a trench 226 or a plurality of trenches 226 formed in the mold compound 224. As described above, the trench 226 can be formed by a laser cutting or etching process. The trench 226 can form a wall that substantially surrounds the second die 210 and third die 214. If the trench 226 is continuous (i.e., trench 406 in FIG. 4), the trench 226 completely surrounds both dies. Alternatively, if the trench 226 is discontinuous (i.e., trench 506 in FIG. 5), the trench 226 does not completely surround both dies.

Once the trench 226 is formed in the mold compound 224, the trench 226 can be filled with conductive material such as copper. In addition, a conductive plane 228 can be coupled to the conductive material-filled trench 226 to form a conductive shield that separates the first die 206 from the second die 210 and third die 214. In this embodiment, the conductive plane 228 is planar. In an alternative embodiment, however, the conductive plane 228 is a conductive shield layer that is non-planar. In another embodiment, the conductive plane 228 can be a layer of the first substrate 208 (e.g., a ground layer). The conductive shield can reduce the electromagnetic interference between the first die 206 and the second and third dies 210, 214.

In one embodiment, it may be necessary or desirable to only shield the first die 206 and the second die 210 from one another. In this embodiment, the trench 226 may only be formed in the mold material 224 around the second die 210. In this embodiment, the second die 210 would be shielded from both the first die 206 and the third die 214, but the first die 206 would not be shielded from the third die 214. Alternatively, a trench 226 can be formed between the second die 210 and third die 214 to shield all three dies from one another.

In an alternative embodiment, vias can be fabricated in the mold compound 224 in addition to or instead of the trench 226.

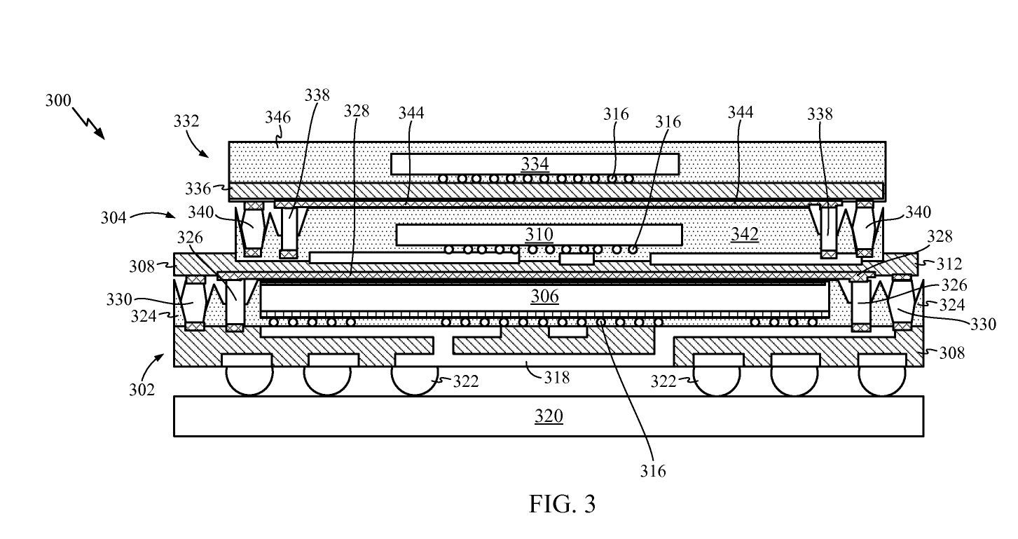

A different embodiment of an electronic package-on-package system 300 with integrated shielding is shown in FIG. 3. The system 300 can include a first package 302, a second package 304, and a third package 332. The first package 302 includes a first die 306 coupled to a first substrate 308. The first die 306 can be conductively coupled by microbumps 316 and an underfill layer 314 to the first substrate 308. The first substrate 308 can be formed of silicon, glass, or any other substrate material. Likewise, the first die 306 can be made of silicon or other die material. The first die 306 can have through-vias or other conductive passages for coupling electrical components in the first package 302. Also, the first substrate 308 can include a plurality of conductive traces 318 for coupling the first die 306 to a chip, another package, or other electrical component. The first substrate 308 can also be coupled to another substrate or printed circuit board 320 by a plurality of solder bumps 322, for example.

Similar to the first package 302, the second package 304 can include a second die 310. The second die 310 is coupled to a second substrate 312. The second die 310 and second substrate 312 can be formed of silicon, for example, or other die and substrate material, respectively. The second die 310 can be coupled to the second substrate 312 by a plurality of microbumps 316. Although not shown, an underfill layer can be disposed between the second die 310 and the second substrate 312 to increase the reliability of the second package 304. In this embodiment, the second substrate 312 can also include a plurality of conductive traces (not shown) for coupling the second die 310 to a chip, another package, or other electrical component.

A mold compound 324 can be disposed between the first substrate 308 and the second substrate 312. The mold compound 324 can be any epoxy-based material for reducing warpage, cracking, or other mechanical defects during the assembly process. A plurality of I/O connections 330 can be formed in the mold compound 324. The I/O connections 330 can couple the first package 302 or second package 304 to other packages, chips, or electrical components.

Similar to the embodiments of FIGS. 1 and 2, a trench 326 can be formed in the mold compound 324. The trench 326 can be formed by laser drilling, etching, or other known process. It is also possible to form a plurality of trenches 326 in the mold compound 324. The trench 326 is formed such that it substantially surrounds the first die 306. As shown in FIGS. 4 and 5, trenches can be formed as a continuous or discontinuous path.

Once the trench 326 is formed in the mold compound 324, conductive material such as copper can fill the trench 326. The conductive material therefore forms a conductive shield or wall that surrounds the first die 306. To provide additional shielding, the conductive material in the trench 326 can be coupled to a conductive plane 328. The conductive plane 328 can be formed of copper or any other conductive material. In addition, the conductive plane 328 can be a metal ground layer or any other layer in the second substrate 312. Alternatively, the conductive plane 328 can be separate from the second substrate 312.

As described above, the conductive plane 328 does not have to be planar. Instead, the conductive plane 328 can have a non-planar configuration as desired. Regardless of the configuration of the conductive plane 328, an integrated conductive shield is formed by coupling the conductive plane 328 to the conductive material-filled trench 326. The integrated conductive shield separates the first die 306 from the second die 310 and therefore substantially reduces or eliminates electromagnetic interference between the dies. In addition, because the integrated conductive shield is integral to the package-on-package system 300, the system 300 does not occupy additional footprint or increase the height thereof.

The third package 332 is similar to the first and second packages. In particular, the third package 332 can include a third die 334 that is coupled to a third substrate 336. The third die 334 and third substrate 336 can be formed of silicon, for example. Alternatively, the third die 334 and the third substrate 336 can be formed of other known die and substrate material, respectively.

The third die 334 can be coupled to the third substrate 336 by a plurality of microbumps 316 and an optional underfill layer (not shown). The third die 334 can be completely or partially surrounded by a mold compound 346. The mold compound 346 can be epoxy-based and similar to the mold compound 324 described above.

Likewise, a different mold compound 342 can be disposed between the second substrate 312 and the third substrate 336. The mold compound 342 can be any epoxy-based material that can, for example, reduce warpage, cracking, or other mechanical defects during assembly. The system 300 can also include I/O connections 340 formed in the mold compound 342 similar to the I/O connections 330 described above. The I/O connections 340 can be useful for providing conductive connections to electrical devices. In other words, the second package 304 and the third package 332 can be coupled to other electrical devices by utilizing the I/O connections 340.

The system 300 can further include another trench 338 or a plurality of trenches 338 formed in the mold compound 342. As described above, the trench 338 can be formed by a laser cutting or etching process. The trench 338 can substantially surround the second die 310. The trench 338 can be continuous (i.e., similar to the trench 406 in FIG. 4) or discontinuous (i.e., similar to the trench 506 in FIG. 5).

Once the trench 338 is formed in the mold compound 342, the trench 338 can be filled with conductive material such as copper. In addition, a second conductive plane 344 can be coupled to the conductive material-filled trench 338 to form a second conductive shield that separates the second die 310 from the third die 334. The second conductive plane 344 can be non-planar and/or be formed as a layer of the third substrate 336 (e.g., a ground metal). The second conductive shield can reduce the electromagnetic interference between the second die 310 and the third die 334.

In another embodiment, the first package 302, second package 304, and/or third package 332 can include a plurality of dies. Shielding can be integrally fabricated in the system 300 to isolate any two dies. Advantageously, the system 300 provides integrated shielding without occupying additional footprint or increasing the overall height thereof.

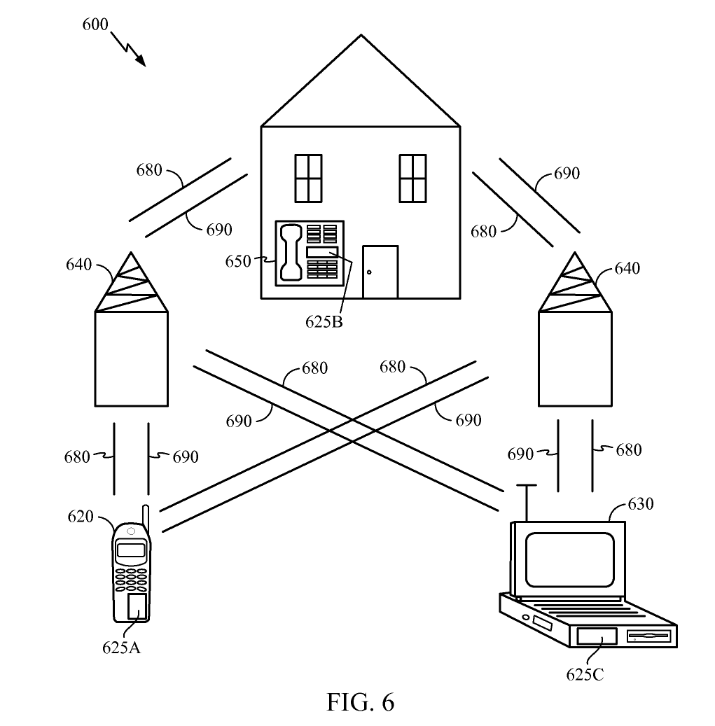

FIG. 6 shows an exemplary wireless communication system 600 in which an embodiment of an electronic package-on-package system with integrated shielding may be advantageously employed. For purposes of illustration, FIG. 6 shows three remote units 620, 630, and 650 and two base stations 640. It should be recognized that typical wireless communication systems may have many more remote units and base stations. Any of remote units 620, 630, and 650, as well as the base stations 640, may include an electronic package-on-package system with integrated shielding such as disclosed herein. FIG. 6 shows forward link signals 680 from the base stations 640 and the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates certain exemplary remote units that may include an electronic package-on-package system with integrated shielding as disclosed herein, the package is not limited to these exemplary illustrated units. Embodiments may be suitably employed in any electronic device in which an electronic package-on-package system with integrated shielding is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. An electronic package-on-package system, comprising:
a first package having a first die;
a second package having a second die and a substrate; and
a conductive shield having a first portion and a second portion, the first portion of the shield being disposed between the first die and the second die and the second portion of the shield being disposed between the substrate of the second package and the first portion of the shield;
wherein, the first portion of the shield is coupled to the second portion of the shield for shielding the first die from the second die.

2. The system of claim 1, wherein the first portion of the conductive shield includes a conductive plane.

3. The system of claim 2, wherein the conductive plane is formed in the first package.

4. The system of claim 1, further comprising a mold material disposed between the substrate and the first portion of the conductive shield.

5. The system of claim 4, further comprising a plurality of trenches defined in the mold material.

6. The system of claim 5, wherein the second portion of the conductive shield is formed in the plurality of trenches.

7. The system of claim 1, wherein the second portion of the conductive shield is continuous or discontinuous.

8. The system of claim 1, further comprising one or more input/output connections for coupling the first package to the substrate.

9. The system of claim 1, wherein the second package includes a plurality of die.

10. The system of claim 1, wherein the first package is positioned substantially above the second package.

11. The system of claim 1, further comprising a third package having a third die, wherein a second conductive shield substantially surrounds the first die for shielding the first die from the third die.

12. The system of claim 1 incorporated into a device selected from a group consisting of a music player, a video player, an entertainment unit, a navigation device, a communications device, a personal digital assistant (PDA), a fixed location data unit, and a computer.

13. An electronic system, comprising:
a first package having a first die coupled to a first substrate;
a second package having a second die coupled to a second substrate;
a mold material disposed between the first substrate and the second substrate;
a conductive plane disposed between the first substrate and the mold material; and
a conductive shield formed in the mold material, the conductive shield coupled to the conductive plane for shielding the first die from the second die.

14. The system of claim 13, wherein the first package is disposed substantially above the second package.

15. The system of claim 13, wherein the conductive shield is continuous or discontinuous.

16. The system of claim 13, wherein the conductive shield is formed in trenches of the mold material.

17. The system of claim 13, wherein the conductive plane is formed in the first package.

18. The system of claim 13, wherein the second package includes a plurality of die.

19. The system of claim 18, wherein the plurality of die is disposed between the conductive plane, conductive shield, and the second substrate.

20. The system of claim 13, further comprising a third package having a third die, wherein a second conductive shield substantially surrounds the first die for shielding the first die from the third die.

21. The system of claim 13 incorporated into a device selected from a group consisting of a music player, a video player, an entertainment unit, a navigation device, a communications device, a personal digital assistant (PDA), a fixed location data unit, and a computer.

22. A method of forming a package-on-package system with integrated shielding, comprising:
providing a first package and a second package, the first package having a first die and the second package having a second die and a substrate;
providing a conductive plane between the first die and the second die;
applying a mold material between the substrate and the conductive plane;
forming a plurality of trenches in the mold material;
depositing a conductive material in the plurality of trenches to form a conductive shield; and
coupling the conductive shield to the conductive plane for shielding the first die from the second die.

23. The method of claim 22, wherein the conductive shield is continuous or discontinuous.

24. The method of claim 22, wherein the conductive plane is formed in the first package.

25. The method of claim 22, wherein the second package includes a plurality of die.

26. The method of claim 30, wherein the plurality of die is disposed between the conductive plane, conductive shield, and substrate.

27. The method of claim 22 incorporated into a device selected from a group consisting of a music player, a video player, an entertainment unit, a navigation device, a communications device, a personal digital assistant (PDA), a fixed location data unit, and a computer.

28. An electronic package-on-package system, comprising:
a first package having a first die;
a second package having a second die and a substrate;
a first means for shielding disposed between the first die and the second die;
a mold material disposed between the substrate and the first means for shielding; and
a second means for shielding formed in the mold material, the first means for shielding coupled to the second means for shielding for shielding the first die from the second die.

29. The system of claim 28, further comprising one or more input/output connections for coupling the first package to the substrate.

30. The system of claim 28, wherein the second means for shielding is continuous or discontinuous.

31. The system of claim 28, wherein the second means for shielding is formed in trenches in the mold material.

32. The system of claim 28, wherein the first means for shielding is formed in the first package.

33. The system of claim 28, wherein the second package includes a plurality of die.

34. The system of claim 33, wherein the plurality of die is disposed between the first means for shielding, the second means for shielding, and the substrate.

35. The system of claim 28, further comprising a third package having a third die, wherein a second conductive shield substantially surrounds the first die for shielding the first die from the third die.

36. The system of claim 28 incorporated into a device selected from a group consisting of a music player, a video player, an entertainment unit, a navigation device, a communications device, a personal digital assistant (PDA), a fixed location data unit, and a computer.
